(19) United States
(12) Patent Application Publication
(10) Pub. No.: US 2013/0087441 A1
(43) Pub. Date: Apr. 11, 2013

(54) TOUCH PANEL AND METHOD OF MANUFACTURING THE SAME

(71) Applicant: SAMSUNG ELECTRO-MECHANICS CO., LTD, Gyunggi-do (KR)

(72) Inventors: Young Jae Kim, Gyunggi-do (KR); Youn Soo Kim, Seoul (KR); Ho Joon Park, Seoul (KR)

(73) Assignee: SAMSUNG ELECTRO-MECHANICS CO., LTD., Gyunggi-do (KR)

(21) Appl. No.: 13/644,751

(22) Filed: Oct. 4, 2012

(30) Foreign Application Priority Data
Oct. 7, 2011 (KR) 10-2011-0102513

(51) Int. Cl. H03K 17/96; H03K 99/00

(52) U.S. Cl. CPC H03K 17/9618; H03K 99/00
USPC 200/5 A; 29/622

(57) ABSTRACT

Disclosed herein are a touch panel and a method of manufacturing the same. The touch panel 100 includes a transparent substrate 110 having concave portions 115 formed therein in a mesh pattern, and electrode patterns 120 formed in the concave portions 115 and made of a metal, the electrode patterns 120 being patterned in a predetermined pattern so that empty spaces 117 are present in the concave portions 115. After the concave portions 115 are formed in the transparent substrate 110 in a mesh pattern, a photolithography process is performed to thereby form the electrode patterns 120 only in the concave portions 115 exposed from the photoresist 140, such that the photolithography process may be performed at a relatively large size, thereby making it possible to reduce manufacturing costs.

### CROSS REFERENCE TO RELATED APPLICATION

This application claims the benefit of Korean Patent Application No. 10-2011-0102513, filed on Oct. 9, 2011, entitled “Touch Panel and Method of Manufacturing the Same”, which is hereby incorporated by reference in its entirety into this application.

### BACKGROUND OF THE INVENTION

1. Technical Field

The present invention relates to a touch panel and a method of manufacturing the same.

2. Description of the Related Art

Alongside the growth of computers using digital technology, devices assisting computers have also been developed, and personal computers, portable transmitters and other personal information processors execute processing of text and graphics using a variety of input devices such as a keyboard and a mouse.

While the rapid advancement of the information-based society has been widening the use of computers more and more, there have been occurring the problems of it being difficult to efficiently operate products using only the keyboard and mouse as being currently responsible for the input device function. Thus, the demand for a device that is simple, has minimum malfunction, and has the capability to easily input information is increasing.

Furthermore, current techniques for input devices exceed the level of fulfilling general functions and thus are progressing towards techniques related to high reliability, durability, innovation, designing and manufacturing. To this end, a touch panel has been developed as an input device capable of inputting information such as text and graphics.

The touch panel is mounted on the display surface of an image display device such as an electronic organizer, a flat panel display including a liquid crystal display (LCD), a plasma display panel (PDP), an electroluminescence (El) element or the like, or a cathode ray tube (CRT), so that a user selects the information desired while viewing the image display device.

The touch panel is classifiable as a resistive type, a capacitive type, an electromagnetic type, a surface acoustic wave (SAW) type, and an infrared type. The type of touch panel selected is one that is adapted for an electronic product in consideration of not only signal amplification problems, resolution differences and the degree of difficulty of designing and manufacturing technology but also in light of optical properties, electrical properties, mechanical properties, resistance to the environment, input properties, durability and economic benefits of the touch panel. In particular, resistive and capacitive types are prevalently used in a broad range of fields currently.

In the touch panel, an electrode pattern is generally formed using indium tin oxide (ITO). The ITO has excellent electric conductivity, but a raw material thereof, that is, indium is a rare earth metal and is thus expensive, and besides, it is expected to run out in 10 years and therefore, supply and demand thereof will not be smooth.

For this reason, studies for forming an electrode pattern using a metal has been actively conducted, as disclosed in Korean Patent Laid-Open Publication No. 10-2010-0091497. When the electrode pattern is formed using a metal, the metal has more excellent electric conductivity and more smooth supply and demand, as compared with the ITO. However, when the electrode pattern is formed using a metal in the prior art, it needs a photolithography process. That is, the electrode pattern is formed by the photolithography process, which needs expensive exposure equipment exposing up to the unit of micrometer (μm), such that the manufacturing costs thereof is very expensive. In addition, when the electrode pattern is formed by a general photolithography process, the electrode pattern is protruded from a transparent substrate to thereby be structurally weakened.

### SUMMARY OF THE INVENTION

The present invention has been made in an effort to provide a touch panel in which after concave portions are formed in a transparent substrate in a mesh pattern, a photolithography process is performed to form electrode patterns only in the concave portions exposed from the photoresist, thereby reducing manufacturing costs and securing structural stability, and a method of manufacturing the same

According to a preferred embodiment of the present invention, there is provided a touch panel, including: a transparent substrate having concave portions formed therein in a mesh pattern; and electrode patterns formed in the concave portions and made of a metal, the electrode patterns being patterned in a predetermined pattern so that empty spaces are present in the concave portions.

The electrode patterns may be formed only in the concave portions.

The touch panel may further include electrode wirings formed integrally with the electrode patterns in the concave portions and made of a metal to be connected to the electrode patterns.

The metal may be copper (Cu), aluminum (Al), gold (Au), silver (Ag), titanium (Ti), palladium (Pd), chrome (Cr), or a combination thereof.

A surface of the electrode pattern may be subjected to a black oxide process.

According to a preferred embodiment of the present invention, there is provided a method of manufacturing a touch panel, the method including: (A) forming concave portions in a transparent substrate in a mesh pattern; (B) applying a photoresist to the transparent substrate and selectively patterning the photoresist so that opening portions are formed in the photoresist; and (C) forming electrode patterns in the concave portions exposed through the opening portions, the electrode patterns being made of a metal.

The method may further include, after step (C), removing the photoresist.

The method may further include, after step (C), polishing the metal so that the electrode patterns remain only in the concave portions.

At step (A), the concave portions may be formed using a dicing saw.

A step (C), electrode wirings may be formed in the concave portions, the electrode wirings made of a metal and connected to the electrode patterns, simultaneously with forming the electrode patterns.

At step (C), the metal may be copper (Cu), aluminum (Al), gold (Au), silver (Ag), titanium (Ti), palladium (Pd), chrome (Cr), or a combination thereof.

The method may further include, after step (C), performing a black oxide process on a surface of the electrode pattern.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

### BRIEF DESCRIPTION OF THE DRAWINGS

FIGS. 1A and 1B are each plan view and enlarged cross-sectional view of the touch panel according to a preferred embodiment of the present invention;

FIGS. 2A and 2B are plan views and enlarged cross-sectional views showing the step of forming the concave portions with mesh pattern in transparent substrate, in the method of manufacturing a touch panel according to a preferred embodiment of the present invention;

FIGS. 3A and 3B are plan views and enlarged cross-sectional views showing the step of applying a photoresist to the transparent substrate and selectively patterning the photoresist so that opening portions are formed in the photoresist, in the method of manufacturing a touch panel according to a preferred embodiment of the present invention;

FIGS. 4A and 4B are plan views and enlarged cross-sectional views showing the step of forming electrode patterns being made of a metal in the concave portions exposed through the opening portions, in the method of manufacturing a touch panel according to a preferred embodiment of the present invention;

FIGS. 5A and 5B are plan views and enlarged cross-sectional views showing the step of removing the photoresist, in the method of manufacturing a touch panel according to a preferred embodiment of the present invention;

FIGS. 6A and 6B are plan views and enlarged cross-sectional views showing the step of polishing the metal with pad so that the electrode patterns remain only in the concave portions, in the method of manufacturing a touch panel according to a preferred embodiment of the present invention;

FIG. 7 is a plan view of a capacitive type touch panel forming the electrode patterns on both surfaces of the transparent substrate, as a touch panel according to a preferred embodiment of the present invention;

FIG. 8 is a plan view of a capacitive type touch panel formed by bonding two transparent substrates by forming electrode pattern on one surface of the transparent substrate, as a touch panel according to a preferred embodiment of the present invention; and

FIG. 9 is a plan view of a resistive type touch panel wherein dot spacers are formed, as a touch panel according to a preferred embodiment of the present invention.

### DESCRIPTION OF THE PREFERRED EMBODIMENTS

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the gist of the present invention.

Hereinafter, preferred embodiments of the present invention will be described in detail with reference to the accompanying drawings.

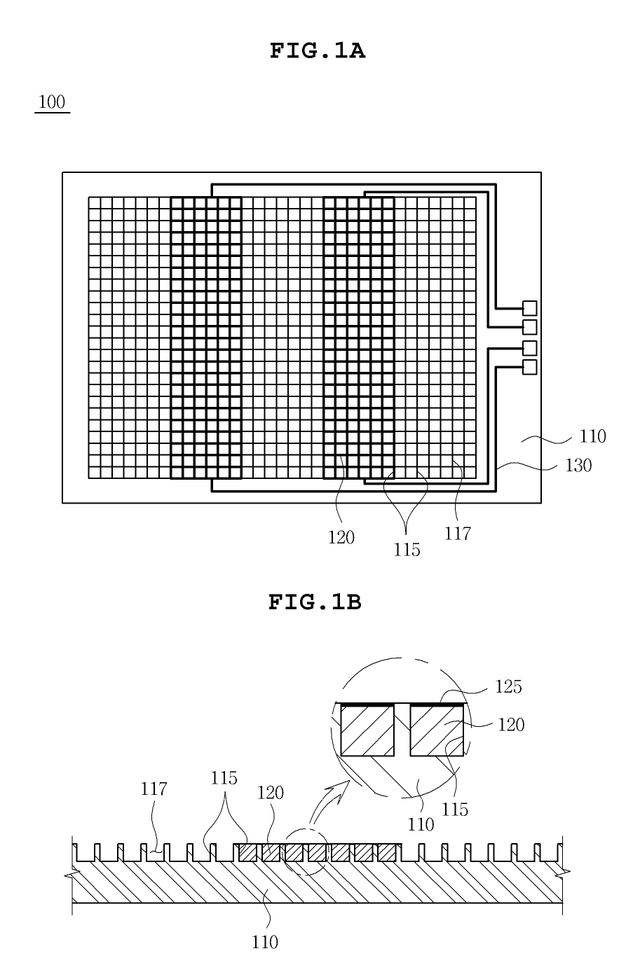

FIGS. 1A and 1B are each a plan view and an enlarged cross-sectional view of a touch panel according to a preferred embodiment of the present invention.

As shown in FIGS. 1A and 1B, a touch panel 100 according to a preferred embodiment of the present invention is configured to include a transparent substrate 110 having concave portions 115 formed therein in a mesh pattern, and electrode patterns 120 formed in the concave portions 115 and made of a metal, the electrode patterns 120 being patterned in a predetermined pattern so that empty spaces 117 are present in the concave portions 115.

The transparent substrate 110 serves to provide a region in which the electrode patterns 120 and electrode wirings 130 are to be formed. Here, the transparent substrate 110 needs to have supporting force capable of supporting the electrode patterns 120 and the electrode wirings 130 and transparency through which a user can recognize an image provided from an image display apparatus. In consideration of the supporting force and the transparency, the transparent substrate 110 may be made of polyethyleneterephthalate (PET), polycarbonate (PC), polymethylmethacrylate (PMMA), polyethylenenaphthalate (PEN), polyethersulfone (PES), cyclic olefin copolymer (COC), triacetylcellulose (TAC) film, polyvinyl alcohol (PVA) film, polyimide (PI) film, polystyrene (PS), biaxially oriented polystyrene (BOPS; containing K resin), glass or tempered glass, and so on, but is not particularly limited thereto.

In addition, the concave portions 115 depressed in a thickness direction are formed in the transparent substrate 110 in a mesh pattern. In this case, the concave portions 115 are provided with the electrode patterns 120 and thus, the electrode patterns 120 are also formed in a mesh pattern. A detailed description thereof will be described later.

The electrode pattern 120 serves to generate signals when the touch panel is touched by a user to allow a controller to recognize the touched coordinates. Here, the electrode pattern 120 may be made of copper (Cu), aluminum (Al), gold (Au), silver (Ag), titanium (Ti), palladium (Pd), chrome (Cr), or a combination thereof. More specifically, the electrode pattern 120 may preferably be made of copper (Cu), aluminum (Al), gold (Au), and silver (Ag), which have high electric conductivity, but may also be made of all metals having electric conductivity. In addition, when the electrode pattern 120 is made of copper (Cu), a surface of the electrode pattern 120 may be subjected to a black oxide process 125. Here, the black oxide process 125 refers to a process of oxidizing a surface of the electrode pattern 120 to thereby precipitate Cu2O or CuO, wherein Cu2O is colored with brown to thereby be named brown oxide and CuO is colored with black to thereby be named black oxide. As described above the surface of the electrode pattern 120 is subjected to the black oxide process 125, thereby making it possible to prevent light from being reflected on the electrode pattern 120 and thus to improve visibility of the touch panel 100.

In addition, the electrode pattern 120 is formed in the concave portion 115 of the transparent substrate 110 and the concave portion 115 is formed in a mesh pattern, such that the electrode pattern 120 formed in the concave portion 115 is also formed in a mesh pattern. However, the electrode patterns 120 are not formed in all of the portions of the concave portions 115 but are patterned in a predetermined pattern so that empty spaces 117 are present in some of the concave portions 115. In other words, the electrode patterns 120 are entirely patterned in a predetermined pattern and are patterned in a mesh pattern having a fine unit (approximately, a unit of micrometer (μm)). For example, as shown in FIG. 1A, the electrode patterns 120 may be entirely patterned in a bar-type pattern and the bar-type pattern may be configured of a mesh pattern. However, the electrode pattern 120 is formed in a bar-type pattern by way of example and thus is not particularly limited thereto. That is, the electrode pattern 120 may be patterned in all of patterns publicly known in the art, such as a diamond pattern, a rectangular pattern, a triangular pattern, a circular pattern, or the like.

Meanwhile, the concave portions 115, which are the empty spaces 117, may be present, in a mesh pattern, even in portions in which the electrode patterns 120 are not formed. Therefore, since the mesh pattern is present in both the portion in which the electrode pattern 120 is formed and the portion in which the electrode pattern 120 is not formed, a user may barely recognize the electrode pattern 120, thereby making it possible to improve visibility of the touch panel 100.

In addition, the electrode patterns 120 may be formed only within the concave portions 115. More specifically, the electrode patterns 120 may remain only within the concave portions 115 by polishing portions protruded from the transparent substrate 110. Finally, the electrode patterns 120 are buried in the concave portions 115, thereby making it possible to secure structural reliability of the electrode patterns 120.

In addition, the electrode wirings 130 connected to the electrode patterns 120 to thereby receive electrical signals may be formed. Here, the electrode wiring 130 may be formed integrally with the electrode pattern 120 in the concave portion 115 and be made of a metal. As such, the electrode wiring 130 is formed integrally with the electrode pattern 120, thereby making it possible to simplify a manufacturing process of the touch panel 100 and reduce a lead time. Furthermore, the electrode wiring 130 is formed simultaneously with forming of the electrode pattern 120, thereby making it possible to omit a bonding process between the electrode wiring 130 and the electrode pattern 120 and as a result, to previously prevent steps or bonding defects between the electrode pattern 120 and the electrode wiring 130 from occurring beforehand.

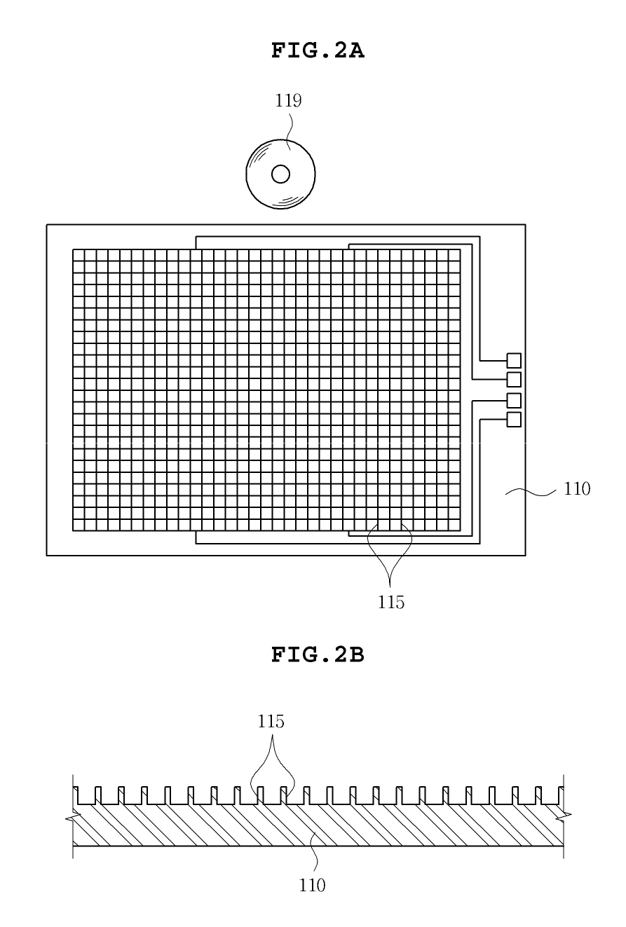

FIGS. 2 to 6 are plan views and enlarged cross-sectional views sequentially showing the process of manufacturing a touch panel according to a preferred embodiment of the present invention.

As shown in FIGS. 2 to 6, a method of manufacturing a touch panel 100 according to the preferred embodiment of the present invention may include (A) forming concave portions 115 in a transparent substrate 110 in a mesh pattern; (B) applying a photoresist 140 to the transparent substrate 110 and selectively patterning the photoresist 140 so that opening portions 145 are formed therein; and (C) forming electrode patterns 120 in the concave portions 115 exposed through the opening portions 145, the electrode patterns 120 being made of a metal.

First, as shown in FIG. 2, the concave portions 115 are formed in the transparent substrate 110 in a mesh pattern. Here, the concave portions 115 are formed by removing the transparent substrate 110 in a thickness direction using a dicing saw 119. In this case, the concave portions 115 are patterned in a mesh pattern having a fine unit (appropriately, a unit of micrometer (μm)). Meanwhile, the electrode patterns 120 may be finally formed in the concave portions 115 and electrode wirings 130 may also be formed therein, as needed.

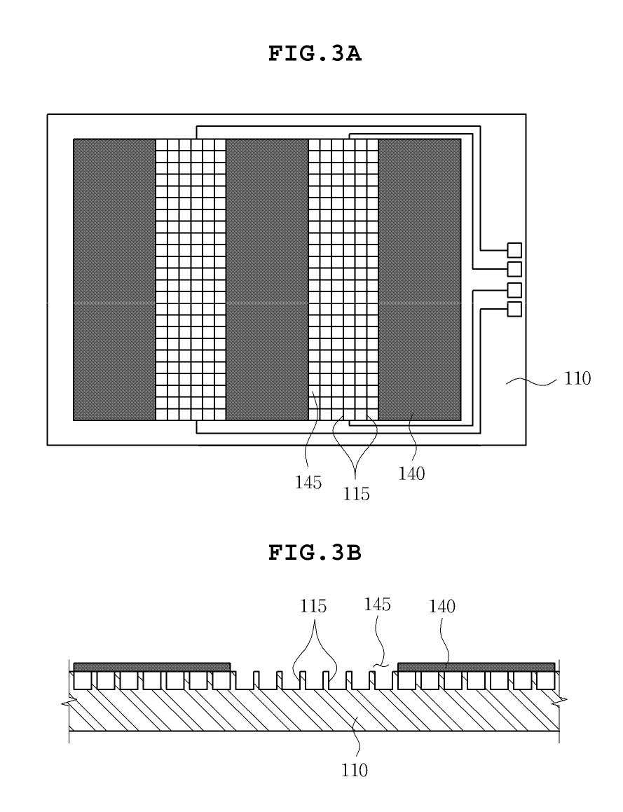

Next, as shown in FIG. 3, the photoresist 140 is applied to the transparent substrate 110 and the photoresist 140 is selectively patterned so that the opening portions 145 are formed therein. Here, as the photoresist 140, a dry film and a photocurable resin including a liquid photosensitive material may be used.

More specifically, the photoresist 140 is first applied to the transparent substrate 110 and then an exposure process is performed thereon, the exposure process irradiating light on portions (positive type photoresist) in which the opening portions 145 are to be formed or portions other than the portions (negative type photoresist) according to the type of photoresist 140. Then, a development process dissolving and removing the portions in which the opening portions 145 are to be formed is performed, thereby forming the opening portions 145 in the photoresist 140.

Meanwhile, the opening portions 145 of the photoresist 140 finally decide a predetermined pattern of the electrode patterns 120, such that the photoresist 140 is selectively patterned so that the opening portions 145 are formed in consideration of the predetermined pattern of the electrode patterns 120 to be formed. For example, in order to form the electrode patterns 120 in a bar-type pattern, the opening portions 145 of the photoresist 140 are also patterned in a bar-type pattern, as shown in FIG. 3A.

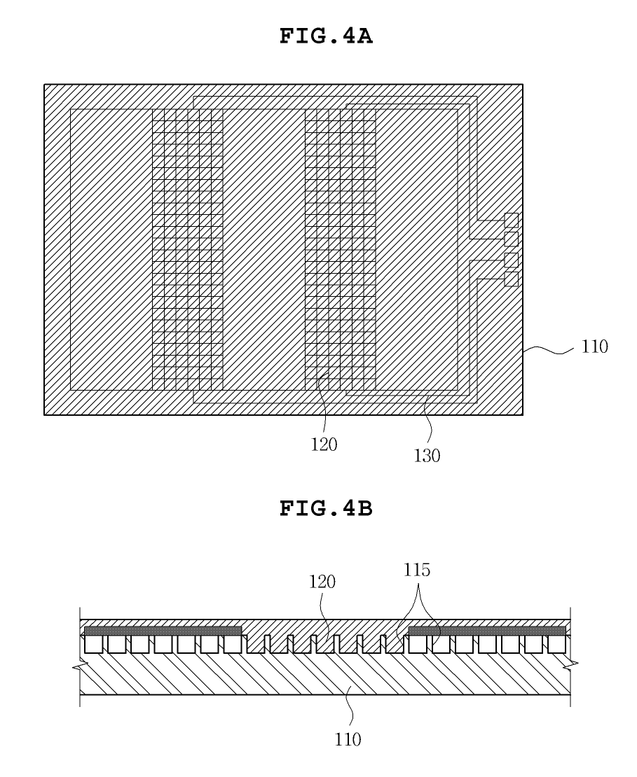

Then, as shown in FIG. 4, the electrode patterns 120 are formed in the concave portions 115 exposed through the opening portions 145, the electrode patterns 120 being made of a metal. Here, the electrode patterns 120 may be formed by a deposition process using a sputtering method, an E-beam evaporation method, or the like. However, the electrode patterns 120 is not always formed by a deposition process but may be formed by a plating process or the like. Through the deposition process or the plating process as described above, the electrode patterns 120 are formed in the concave portions 115 exposed through the opening portions 145 of the photoresist 140.

In addition, the electrode wirings 130 connected to the electrode patterns 120 may also be formed in the concave portions 115 using a metal, simultaneously with forming the electrode patterns 120. In other words, through the deposition process or the plating process as described above, the electrode wirings 130 may be formed simultaneously with forming the electrode patterns 120.

Meanwhile, the electrode patterns 120 and the electrode wrings 130 may be made of copper (Cu), aluminum (Al), gold (Au), silver (Ag), titanium (Ti), palladium (Pd), chrome (Cr), or a combination thereof.

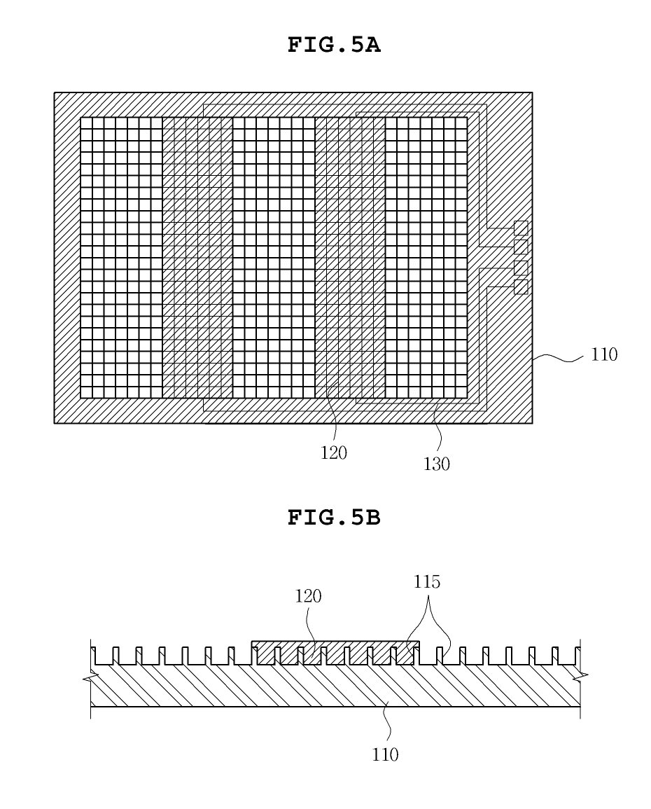

Then, as shown in FIG. 5, the photoresist 140 is removed. At this step, if the photoresist 140 is removed, the metal formed in the photoresist 140 is also removed therewith, such that only the electrode patterns 120 formed in the concave portions 145 of the photoresist 140 remain. Therefore, a predetermined pattern of the electrode pattern 120 is determined according to a shape of the opening portion 145 of the photoresist 140. For example, as shown in FIG. 3A, if the opening portion 145 of the photoresist 140 has a bar-type pattern, the electrode pattern 120 also has a bar-type pattern as shown in FIG. 5A.

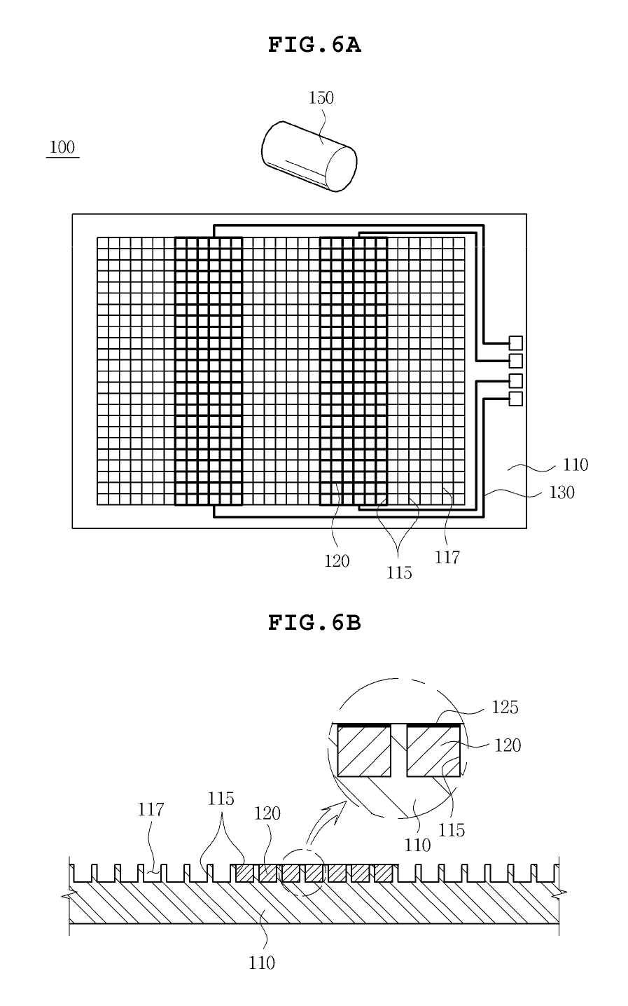

Then, as shown in FIG. 6, the metal is polished with a pad 150 so that the electrode patterns 120 remain only in the concave portions 115. If the electrode patterns 120 are formed by the deposition process or the plating process at the aforementioned step, portions of the electrode patterns 120 may be protruded from the transparent substrate 110 as well as the electrode patterns 120 may be formed in the concave portions 115 of the transparent substrate 110. Therefore, at this step, the electrode patterns 120 protruded from the transparent substrate 110 are removed by performing polishing, to thereby allow the electrode patterns 120 to remain only in the concave portions 115. As described above, the electrode patterns 120 remain only in the concave portions 115 by performing polishing, thereby making it possible to secure structural stability of the electrode patterns 120.

Meanwhile, when the electrode pattern 120 is made of copper (Cu), a surface of the electrode pattern 120 may be subjected to a black oxide process 125. As described above, the surface of the electrode pattern 120 is subjected to the black oxide process 125, thereby making it possible to prevent light from being reflected on the electrode pattern 120 and thus to improve visibility of the touch panel 100.

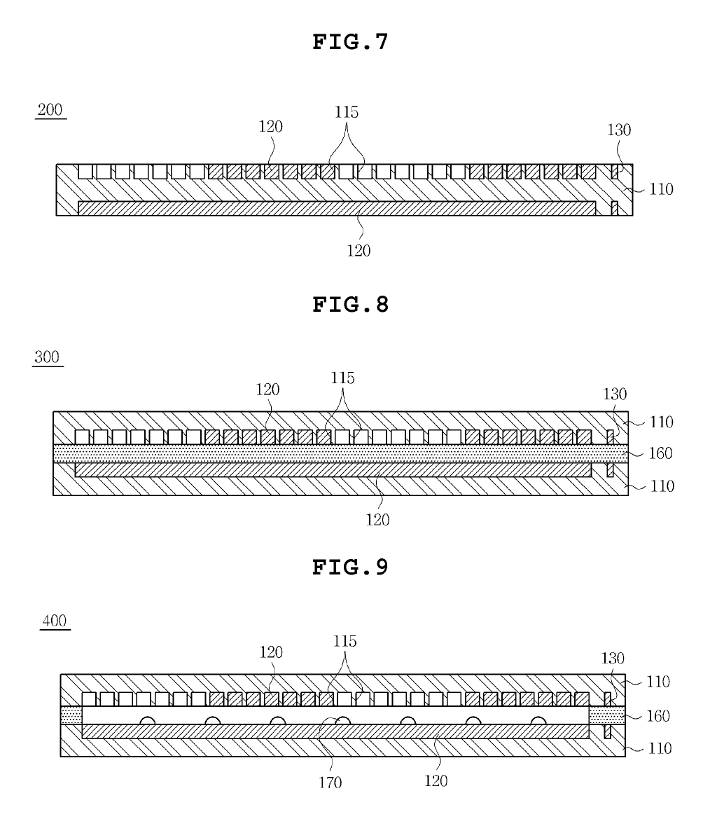

FIGS. 7 to 9 are cross-sectional views of a touch panel manufactured using a preferred embodiment of the present invention.

As shown in FIG. 7, a capacitive type touch panel 200 may be manufactured by forming the electrode patterns 120 on both surfaces of the transparent electrode 110, respectively. In addition, as shown in FIGS. 8 and 9, a mutual capacitive type touch panel 300 (see FIG. 8) or a resistive type touch panel 400 (see FIG. 9) may be manufactured by preparing two transparent substrates 110 including the electrode patterns 120 formed on one surface thereof and bonding the two transparent substrates 110 to each other using an adhesive layer 160 so that the electrodes patterns 120 face each other. Here, in the case of the mutual capacitive type touch panel 300 (see FIG. 8), the adhesive layer 160 is bonded to the entire surface of the transparent electrode 110 so that the two transparent electrodes 110 facing each other are insulated from each other. Meanwhile, in the case of the resistive type touch panel 400 (see FIG. 9), the adhesive layer 160 is bonded only to the edge of the transparent substrate 110 so that the two electrode patterns 120 facing each other are in contact with each other when pressure of an input unit is operated, and dot spacers 170 are provided on the exposed surfaces of the electrode patterns 120, the dot spacer providing repulsive force when the pressure of the input unit is removed so that the electrode patterns 120 are returned to their original positions.

According to the present invention, after the concave portions are formed in the transparent substrate in a mesh pattern, the photolithography process is performed to thereby form the electrode patterns only in the concave portions exposed from the photoresist, such that the photolithography process may be performed at a relatively large size, thereby making it possible to reduce a manufacturing cost.

In addition, according to the present invention, the electrode patterns are formed in the concave portions of the transparent substrate, such that the electrode patterns are not protruded from the transparent substrate, thereby making it possible to secure structural stability of the electrode patterns.

Although the preferred embodiments of the present invention have been disclosed for illustrative purposes, they are for specifically explaining the present invention and thus a touch panel and a method of manufacturing the same according to the present invention are not limited thereto, but those skilled in the art will appreciate that various modifications, additions and substitutions are possible, without departing from the scope and spirit of the invention as disclosed in the accompanying claims. Accordingly, any and all modifications, variations or equivalent arrangements should be considered to be within the scope of the invention, and the detailed scope of the invention will be disclosed by the accompanying claims.

What is claimed is:

1. A touch panel, comprising:
a transparent substrate having concave portions formed therein in a mesh pattern; and
electrode patterns formed in the concave portions and made of a metal, the electrode patterns being patterned in a predetermined pattern so that empty spaces are present in the concave portions.

2. The touch panel as set forth in claim 1, wherein the electrode patterns are formed only in the concave portions.

3. The touch panel as set forth in claim 1, further comprising electrode wirings formed integrally with the electrode patterns in the concave portions and made of a metal to be connected to the electrode patterns.

4. The touch panel as set forth in claim 1, wherein the metal is copper (Cu), aluminum (Al), gold (Au), silver (Ag), titanium (Ti), palladium (Pd), chrome (Cr), or a combination thereof.

5. The touch panel as set forth in claim 1, wherein a surface of the electrode pattern is subjected to a black oxide process.

6. A method of manufacturing a touch panel, the method comprising:
(A) forming concave portions in a transparent substrate in a mesh pattern;
(B) applying a photoresist to the transparent substrate and selectively patterning the photoresist so that opening portions are formed in the photoresist; and
(C) forming electrode patterns in the concave portions exposed through the opening portions, the electrode patterns being made of a metal.

7. The method as set forth in claim 6, further comprising, after step (C), removing the photoresist.

8. The method as set forth in claim 6, further comprising, after step (C), polishing the metal so that the electrode patterns remain only in the concave portions.

9. The method as set forth in claim 6, wherein at step (A), the concave portions are formed using a dicing saw.

10. The method as set forth in claim 6, wherein at step (C), electrode wirings are formed in the concave portions, the electrode wirings made of a metal and connected to the electrode patterns, simultaneously with forming the electrode patterns.

11. The method as set forth in claim 6, wherein at step (C), the metal is copper (Cu), aluminum (Al), gold (Au), silver (Ag), titanium (Ti), palladium (Pd), chrome (Cr), or a combination thereof.

12. The method as set forth in claim 6, further comprising, after step (C), performing a black oxide process on a surface of the electrode pattern.
